(19) United States
(12) Patent Application Publication
(10) Pub. No.: US 2026/0134322 A1
(43) Pub. Date: May 14, 2026

(54) TECHNIQUES FOR FLUX-BASED SUPERCONDUCTING QUBIT READOUT AND RELATED SYSTEMS AND METHODS

(71) Applicant: Atlantic Quantum Corp., Cambridge, MA (US)

(72) Inventors: Youngkyu Sung, Cambridge, MA (US); Tim Menke, Boston, MA (US); Sergey Novikov, Cambridge, MA (US); Konstantin Nesterov, Cambridge, MA (US); Bharath Kannan, Cambridge, MA (US)

(73) Assignee: Atlantic Quantum Corp., Cambridge, MA (US)

(21) Appl. No.: 18/939,146

(22) Filed: Nov. 6, 2024

(51) Int. Cl. G06N 10/40; H03K 3/38

(52) U.S. Cl. CPC G06N 10/40; H03K 3/38

(57) ABSTRACT

Techniques are described for flux-based readout of superconducting qubits. A superconducting qubit whose state is to be measured is coupled to a flux qubit which acts as a transducer, mapping the state of the superconducting qubit to a state of the flux qubit. The state of the flux qubit can be then measured using a flux-based readout system, which allows for a more lightweight signal processing configuration compared with conventional resonator and microwave probe signal approaches.

### BACKGROUND

Quantum computing platforms promise to provide solutions to many computationally intractable problems. In a quantum computing platform, information is stored in quantum bits or “qubits,” and the power of the platform generally increases with the number of qubits that can be independently and simultaneously controlled. In quantum computing platforms comprising qubits such as trapped ions or neutral atoms, directed electromagnetic waves (e.g., microwaves, optical beams) implement independent qubit manipulations, while platforms comprising qubits such as electron dots or superconducting circuits use guided RF or microwave beams.

### SUMMARY

According to some aspects, the techniques described herein relate to a system including: a superconducting qubit; a flux qubit coupled to the superconducting qubit via a coupling element; and a readout system coupled to the flux qubit and configured to measure a current in the flux qubit that is indicative of a quantum state of the superconducting qubit.

According to some aspects, the techniques described herein relate to a method including: controlling a flux bias of a flux qubit such that a first transition frequency corresponding to a level transition of the flux qubit is resonant with a second transition frequency corresponding to a level transition of a superconducting qubit, the superconducting qubit being coupled to the flux qubit via a coupling element; applying at least one microwave pulse to the flux qubit that drives the level transition of the flux qubit; controlling the flux bias of the flux qubit to generate a persistent current in the flux qubit; and measuring the persistent current in the flux qubit using a readout system.

According to some aspects, the techniques described herein relate to a system including: a plurality of qubit modules, each qubit module including: a superconducting qubit; a coupling element; and a flux qubit coupled to the superconducting qubit via a coupling element; and a readout system coupled to the flux qubit in each of the plurality of qubit modules, and configured to measure a current in the flux qubit in a respective qubit module that is indicative of a quantum state of the superconducting qubit to which the flux qubit in the respective qubit module is coupled.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF DRAWINGS

Various aspects and embodiments will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIG. 1 is a schematic of a system suitable for practicing aspects of the present disclosure, according to some embodiments;

FIGS. 2A-2F depict energy level diagrams of a flux qubit and superconducting qubit system, according to some embodiments;

FIG. 3 is an illustrative implementation of the system of FIG. 1, according to some embodiments;

FIG. 4 depicts an illustrative implementation of a flux qubit, coupler and superconducting qubit, according to some embodiments;

FIGS. 5A-5B depict an illustrative current that may flow through a capacitively shunted flux qubit, according to some embodiments;

FIG. 6 depicts an illustrative implementation of a flux qubit, coupler and superconducting qubit, wherein the flux qubit is inductively coupled to a flux readout circuit, according to some embodiments;

FIG. 7 is a flowchart of a method of performing flux-based readout of a superconducting qubit, according to some embodiments; and

FIG. 8 illustrates an example of a computing system environment on which aspects of the disclosure may be implemented.

### DETAILED DESCRIPTION

Qubits can be implemented in superconducting circuits that are engineered to exhibit two or more discrete quantum states at different energy levels. Superconducting qubits typically include one or more non-linear devices, such as Josephson junctions, so that only desired transitions between quantum states can be stimulated. Superconducting circuits also have the advantage of being non-dissipative at low temperatures.

There are several different types of superconducting qubits that exhibit distinct energy levels such that two of the energy levels can be mapped to the logical quantum states |0) and |1). For instance, a charge qubit exhibits energy levels that correspond to different discrete amounts of charge in a small superconducting area, whereas a flux qubit exhibits energy levels that correspond to different persistent current states around a superconducting loop.

Although there are some differences in the way that the various types of superconducting qubits are driven to manipulate their quantum states, measurement of a superconducting qubit is typically performed by coupling the qubit to a resonator. In this process, electromagnetic probe signals (typically microwaves) are sent to the resonator, and the amplitude and/or phase of the signal that is reflected or transmitted from the resonator is measured, which indicates the state of the qubit coupled to the resonator. In practice, this is achieved using systems with complex microwave signal processing configurations, including microprocessors at room temperature, which send signals along a chain of amplifiers across multiple temperature stages to superconducting qubits. Because each resonator generally has a different resonant frequency, probe signals at different frequencies need to be generated and sent to the resonators. In addition, this setup usually requires magnetic microwave isolators and circulators to protect qubits from amplifier back-action.

As a result, readout of superconducting qubits conventionally requires a great deal of physical overhead in the measurement setup. The large number of cables required to route signals between the qubit and room temperature, in addition to their cooling requirements, likely imposes physical space limits, on the potential size of quantum processors of thousands of qubits. Yet, by most estimates, hundreds of thousands to millions of qubits will be needed to perform practically useful quantum computations.

The inventors have recognized and appreciated techniques for flux-based readout of superconducting qubits. In particular, a superconducting qubit whose state is to be measured is coupled to a flux qubit which acts as a transducer, mapping the state of the superconducting qubit to a state of the flux qubit. The state of the flux qubit can be then measured using a flux-based readout system, which allows for a more lightweight signal processing configuration compared with the resonator and probe signal-based approach described above. While the flux-based qubit readout techniques described herein may utilize a microwave drive as part of the readout process, the ability to flux bias a flux qubit means that a single microwave drive frequency can be used to perform readout for any number of qubits, avoiding the significant physical overhead in conventional microwave readout schemes.

According to some embodiments, the flux-based readout techniques described herein may be applied to measure the quantum state of any desired type of superconducting qubit. While a flux qubit is utilized as part of the readout process, the superconducting qubit to which it is coupled may be any type of superconducting qubit, including but not limited to a charge qubit (e.g., a transmon), a flux qubit (e.g., a fluxonium qubit) or a phase qubit. As described below, the flux qubit may be driven such that the quantum state of the superconducting qubit is mapped onto the quantum state of the flux qubit, without destroying the quantum state of the superconducting qubit. The state of the superconducting qubit is then determined by reading the state of the flux qubit via a flux-based readout system. This process may be performed with any type of superconducting qubit so long as the flux qubit can be effectively coupled to the superconducting qubit.

According to some embodiments, the flux bias of the flux qubit may be controlled to bring a transition frequency corresponding to a level transition of the flux qubit in, or out of, resonance with a transition frequency of a level transition of the superconducting qubit. When the flux qubit is flux biased so that these two transitions are resonant with one another, the level transition of the flux qubit may be driven (e.g., with a microwave drive), which conditionally excites the flux qubit according to the state of the superconducting qubit due to level repulsion. For instance, in some cases driving the flux qubit when the transitions are resonant may excite the flux qubit to a higher energy state only when the superconducting qubit is in the |1 [symbol] state, but will not excite the flux qubit to the higher energy state when the superconducting qubit is in the |0 [symbol] state. In this manner, the state of the superconducting qubit is effectively mapped onto a state of the flux qubit. Subsequently, the flux bias of the flux qubit may be controlled to bring the transitions out of resonance.

According to some embodiments, once the state of the superconducting qubit has been mapped onto a state of the flux qubit, the flux bias of the flux qubit may be controlled to produce a persistent current in the flux qubit. The persistent current may be different (e.g., have a different magnitude and/or direction) depending on the state of the flux qubit. This persistent current may be measured by coupling a suitable magnetic flux sensor to the flux qubit, examples of which are described below.

Following below are more detailed descriptions of various concepts related to, and embodiments of, techniques for flux-based superconducting qubit readout. It should be appreciated that various aspects described herein may be implemented in any of numerous ways. Examples of specific implementations are provided herein for illustrative purposes only. In addition, the various aspects described in the embodiments below may be used alone or in any combination, and are not limited to the combinations explicitly described herein.

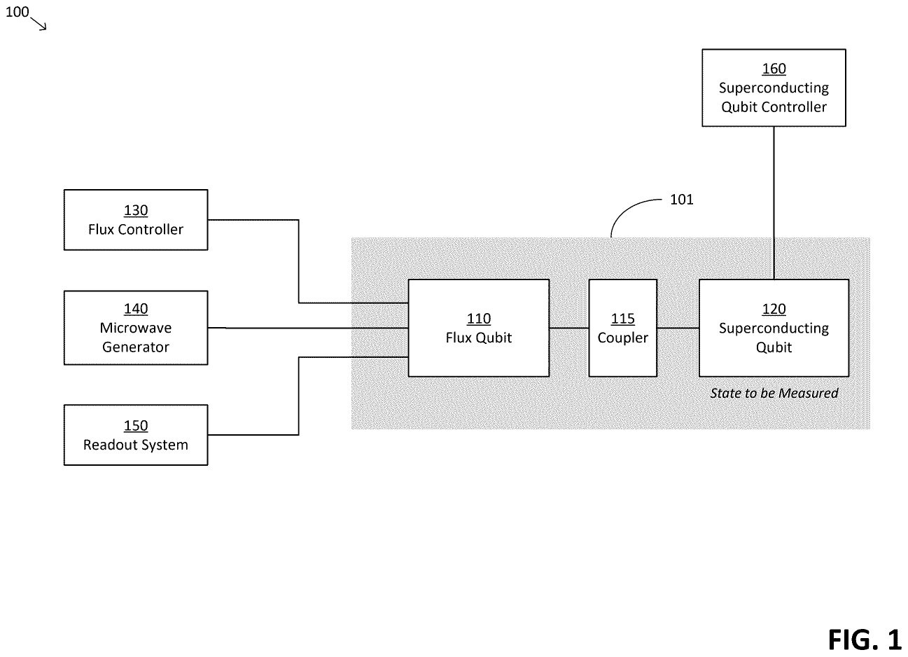

FIG. 1 is a schematic of a system suitable for practicing aspects of the present disclosure, according to some embodiments. System 100 includes a flux qubit 110 coupled to a superconducting qubit 120 via a coupler 115. These three elements are arranged within a low temperature stage 101 denoted by the shaded region, which may represent for instance a cryogenic environment below 4K, such as below 1K, or below 100 mK, or below 50 mK. The flux qubit 110 is coupled to a flux controller 130, a microwave generator 140, and a readout system 150, and the superconducting qubit 120 is coupled to a superconducting qubit controller 160. System 100 is arranged, and may be operated, so that the quantum state of the superconducting qubit 120 may be measured by the readout system 150 by using the flux qubit 110 as a transducer as described herein. While the flux controller 130, microwave generator 140, readout system 150 and superconducting qubit controller 160 are depicted in FIG. 1 as wholly outside of the low temperature stage 101, each may in general be arranged partially within or wholly within the low temperature stage.

Although system 100 depicts a single grouping of a flux qubit 110, coupler 115 and superconducting qubit 120, it will be appreciated that in general a system for quantum computation or other quantum processes will contain many superconducting qubits, and as such system 100 could comprise many qubit ‘modules’ that each comprise the flux qubit 110, coupler 115 and superconducting qubit 120 element as shown. Moreover, any one or more of the flux controller 130, microwave generator 140, readout system 150 and/or superconducting qubit controller 160 may be coupled to any number of flux qubits or superconducting qubits in the manner shown in FIG. 1. For instance, a system may comprise a plurality (e.g., hundreds or thousands) of superconducting qubits 120, each coupled to a respective flux qubit 110 via a respective coupler 115. The superconducting qubit controller 160 may be coupled to any number (including all) of the superconducting qubits 120, and any one or more of the flux controller 130, microwave generator 140 and/or readout system 150 may be coupled to any number (including all) of the flux qubits 110. Moreover, in such a system at least some of the plurality of superconducting qubits 120 may be coupled to other superconducting qubits of the plurality of superconducting qubits. The physical implementation of this coupling between superconducting qubits may depend on the particular type of the superconducting qubit; for example, charge qubits may be coupled together via resonators, whereas flux qubits may be coupled together via inductive coupling and/or resonators. In some embodiments, at least some of the plurality of superconducting qubits 120 are coupled to other superconducting qubits of the plurality of superconducting qubits via a tunable coupler.

It may be appreciated that while superconducting qubit 120 and flux qubit 110 are described herein using different terms, in practice the flux qubit 110 is itself a type of superconducting qubit. These terms are used herein purely to clearly distinguish between one superconducting qubit, whose state is to be measured and which can be any type of superconducting qubit, and the flux qubit, which is a type of superconducting qubit that facilitates this measurement.

In the example of FIG. 1, flux qubit 110 is a superconducting circuit that exhibits energy eigenstates with different persistent currents depending on its flux bias. In some embodiments, the flux qubit 110 is a superconducting circuit arranged as a loop threaded by an external magnetic field and interrupted by a Josephson junction, such that the magnetic flux within the loop is proportional to a phase difference across the Josephson junction. For example, flux qubit 110 may comprise a Josephson junction, a capacitor and an inductor arranged in parallel with one another in a superconducting circuit, with an external magnetic flux threaded through the loop. In some cases, flux qubit 110 may be implemented as a capacitively shunted flux qubit (CSFQ), an example of which is described below.

In the example of FIG. 1, superconducting qubit 120 may include any suitable type of superconducting qubit, including but not limited to, a charge qubit such as a transmon qubit, a gatemon qubit, or an Xmon qubit; a flux qubit such as a fluxonium qubit; or a phase qubit. In some cases, the superconducting qubit 120 may be a logical qubit formed from multiple physical qubits, such as a resonator coupled to an ancilla transmon qubit. In the example of FIG. 1, the coupler 115 may include any one or more elements that provide an electromagnetic coupling between the flux qubit 110 and the superconducting qubit 120. The type of coupler 115 may be selected based on the type of superconducting qubit being used. In some embodiments, the coupler 115 may be, or may comprise, a capacitor and/or may be, or may comprise, an inductor. In some embodiments, the coupler 115 may be, or may comprise, a tunable coupler such as a tunable transmon (e.g., implemented as a capacitively shunted DC superconducting quantum interference device (SQUID)), a tunable inductor and/or a tunable capacitor. In some embodiments, the coupler 115 may be, or may comprise, a dual-mode coupler (e.g., two transmon qubits coupled to each other via a Josephson junction). In some embodiments, the coupler 115 may be, or may comprise, a fluxonium qubit.

In the example of FIG. 1, superconducting qubit controller 160 is configured to manipulate quantum states of the superconducting qubit 120. This may include performing single-qubit gates on the superconducting qubit 120 and/or performing entangling gates (e.g., two-qubit gates) on the superconducting qubit 120 and another superconducting qubit in system 100. In some embodiments, the superconducting qubit controller 160 is configured to direct electromagnetic pulses (e.g., microwave pulses or baseband pulses) to the superconducting qubit 120 (and in some cases to other superconducting qubits at the same time) to perform such state manipulations. In cases where the directed electromagnetic pulses are microwave pulses, the microwave source for such operations may be the same, or a different, microwave source utilized by microwave generator 140 described below. Such electromagnetic pulses may have a frequency corresponding to a level transition of the superconducting qubit 120 (e.g., the frequency corresponding to a transition between the |0 [symbol] and |1 [symbol] states of the superconducting qubit, or a frequency detuned therefrom). This frequency may be different than the frequency of an electromagnetic pulse directed onto the flux qubit 110 by the microwave generator 140. In some embodiments, the superconducting qubit controller 160 is configured to drive the superconducting qubit 120 (and optionally one or more other such superconducting qubits) by directing an electromagnetic pulse through one or more drive lines (also called charge lines) that are capacitively coupled to the superconducting qubit. In some implementations, the superconducting qubit controller 160 is configured in this manner and the superconducting qubit 120 is a fluxonium qubit.

In some embodiments, the superconducting qubit controller 160 is configured to generate flux bias signals (e.g., current signals directed to a flux antenna) to perform state manipulations of the superconducting qubit 120. For example, the superconducting qubit controller 160 may be configured to generate baseband flux signals to dynamically adjust one or more fluxes threaded through a superconducting loop in the superconducting qubit. In some cases, the superconducting qubit 120 may be a flux qubit, such as a fluxonium qubit, and the superconducting qubit controller 160 is configured to control the flux through a superconducting loop in the qubit. In some embodiments, the superconducting qubit controller 160 is configured to direct flux signals and/or microwave signals, as described above, to the superconducting qubit 120.

In the example of FIG. 1, flux controller 130 is configured to control the magnitude of the magnetic flux threaded through the flux qubit 110 (also referred to herein as the magnitude of the flux bias of the flux qubit). For example, flux controller 130 may be configured to control an external magnetic flux threaded through a superconducting loop that is part of the flux qubit 110. In some embodiments, the flux controller 130 is configured to independently control a plurality of magnetic flux biases that are threaded through respective different superconducting loops within the flux qubit 110. In some embodiments, control of an external magnetic flux comprises providing a baseline DC current signal that is fixed, in addition to providing a time-dependent current signal that modulates the baseline DC current signal. For instance, an antenna may be mutually inductively coupled to a superconducting loop of the flux qubit 110, and a current signal may be provided to this antenna to adjust the magnetic flux threaded through the superconducting loop of the flux qubit.

According to some embodiments, controlling the flux bias of the flux qubit 110 by the flux controller 130 comprises directing a flux bias signal (e.g., a current signal) along a flux bias line that is inductively coupled to a superconducting loop of the flux qubit 110 (e.g., inductively coupled via an antenna). In implementations in which superconducting qubit 120 is also a type of flux qubit, the flux controller 130 may also be coupled to the superconducting qubit 120 with one or more independent flux bias lines along which flux bias signals may be directed to control the flux bias of superconducting qubit 120. Alternatively, the superconducting qubit controller 160 may separately control one or more flux bias lines that are coupled to the superconducting qubit 120 and which are distinct from those flux bias lines coupled to the flux qubit 110.

In some embodiments, the flux controller 130 may include digital and analog components, wherein the analog components generate an analog flux bias signal based on digital data supplied by the digital components. Generating an analog flux bias signal in this way may include generating a digital signal and converting the digital signal to an analog signal (e.g., via a digital to analog converter (DAC)), and/or may comprise generating an analog flux bias signal based on one or more digital values. Alternatively, in some embodiments, the flux controller 130 may be an analog device configured to generate an analog flux bias signal and direct that signal to the flux qubit 110 along one or more flux bias lines.

In some embodiments, the flux controller 130 comprises one or more digital devices, which may include a general purpose computing device and/or digital logic devices such as Application-Specific Integrated Circuits (ASICs) or Field Programmable Gate Arrrays (FPGAs), and/or may include low temperature digital logic devices such as one or more cryo-CMOS, adiabatic quantum flux parametron (AQFP), single-flux quantum (SFQ), and/or quantum flux parametron (QFP) devices. As noted above, the flux controller 130 may in some embodiments be partially arranged within the low temperature stage 101. For instance, the flux controller 130 may comprise a room temperature computing device and/or digital logic device coupled to a low temperature AQFP circuit, which is configured to generate an analog flux bias signal based on digital data supplied from the computing device and/or digital logic device. In some embodiments, the flux controller 130 comprises a shift register implemented in low temperature digital logic, such as AQFP, which generates and directs flux bias signals to a plurality of flux qubits 110 (e.g., activates and deactivates a plurality of independent flux bias signals) in accordance with a digital input sequence (e.g., supplied by a room temperature digital logic device).

In the example of FIG. 1, microwave generator 140 is configured to direct microwave signals (e.g., microwave pulses) to the flux qubit 110 (and in some cases to other flux qubits) to drive a level transition of the flux qubit. As described below, by tuning the flux bias of the flux qubit 110 and subsequently directing a microwave pulse onto the flux qubit to drive a level transition of the flux qubit, the quantum state of the superconducting qubit 120 may be mapped onto a state of the flux qubit. The microwave generator 140 may be configured to drive such a transition by applying a microwave pulse that stimulates Rabi oscillations between two energy levels having a transition frequency that corresponds to the frequency of the microwave pulse (or which is detuned therefrom). In some embodiments, the microwave generator 140 is configured to drive the flux qubit 110 (and optionally one or more other such flux qubits) by directing a microwave pulse through one or more drive lines that are capacitively coupled to the flux qubit.

In some embodiments, microwave generator 140 includes a microwave source that produces a microwave signal at a single frequency. As described above, one of the advantages of the techniques described herein may be to reduce the complexity of the microwave electronics needed to read the states of a plurality of superconducting qubits. One way in which this complexity may be reduced is to utilize a microwave source at a single frequency for reading the states of the superconducting qubits (although this single frequency source may be adjusted to slightly different frequencies for driving each individual flux qubit). Although, the microwave generator 140 may also utilize a microwave source at multiple frequencies in some cases, as a microwave source that produces microwave signals at a small number (e.g., 2 or 3) of different frequencies may also have reduced complexity compared with the conventional approach to readout of superconducting qubits.

According to some embodiments, the microwave generator 140 may include digital and analog components, wherein the analog components generate an analog microwave signal based on digital data supplied by the digital components. Generating an analog microwave signal in this way may include generating a digital signal and converting the digital signal to an analog signal (e.g., via a digital to analog converter (DAC)), and/or may comprise generating an analog microwave signal based on one or more digital values. Alternatively, in some embodiments, the microwave generator 140 may be an analog device configured to generate an analog microwave signal and direct that signal to the flux qubit 110.

In some embodiments, the microwave generator 140 comprises one or more digital devices, which may include a general purpose computing device and/or digital logic devices such as ASICs or FPGAs, and/or may include low temperature digital logic devices such as one or more cryo-CMOS, adiabatic quantum flux parametron (AQFP), single-flux quantum (SFQ), and/or quantum flux parametron (QFP) devices. As noted above, the microwave generator 140 may in some embodiments be partially arranged within the low temperature stage 101. For instance, the microwave generator 140 may comprise a room temperature computing device and/or digital logic device coupled to a low temperature AQFP microwave controller, which is configured to generate an analog microwave signal based on digital data supplied from the computing device and/or digital logic device. In some embodiments, the microwave generator 140 comprises one or more mixers implemented in low temperature digital logic, such as AQFP, which are configured to mix an oscillator current and a shaping current to produce a microwave pulse, which is switched on and off based on one or more digital current inputs. The generated microwave pulse(s) may be directed through one or more drives lines to one or more instances of the flux qubit 110.

In the example of FIG. 1, the readout system 150 is configured to measure a quantum state of the flux qubit 110. In some embodiments, the readout system 150 comprises a magnetic flux sensor. Measuring the state of the flux qubit 110 may comprise measuring a flux state of the flux qubit and/or measuring a persistent current within the flux qubit. Measurement of such quantities may include measuring one or more different attributes of the quantity, such as magnitude and/or direction. For instance, the readout system 150 may be configured to measure the direction of a persistent current in the flux qubit 110 and/or to measure the magnitude of a persistent current of the flux qubit. In some embodiments, the readout system 150 comprises a circuit that is inductively coupled to the flux qubit 110, and which measures a current and/or flux state of the flux qubit via this inductively coupling. For example, the readout system 150 may comprise a quantum flux parametron (QFP) circuit as described further below, or may comprise some other inductively coupled device configured to measure the persistent current of the flux qubit to measure the flux state of the flux qubit.

According to some embodiments, the readout system 150 may include digital and analog components, wherein the analog components receive or otherwise generate an analog signal (e.g., a current signal, a voltage signal, etc.) in the readout system based on the state of the flux qubit 110, and wherein the digital components generate digital data based on the analog signal. Generating digital data in this way may include receiving or otherwise generating an analog signal in the readout system 150 and converting the analog signal to a digital signal (e.g., via an analog to digital converter (ADC)). In some embodiments, the readout system 150 may be an analog device configured to receive or otherwise generate an analog signal without converting this signal to a digital signal or generating a digital signal based thereon.

In some embodiments, the readout system 150 comprises one or more digital devices, which may include a general purpose computing device and/or digital logic devices such as ASICs or FPGAs, and/or may include low temperature digital logic devices such as one or more cryo-CMOS, adiabatic quantum flux parametron (AQFP), single flux quantum (SFQ), and/or quantum flux parametron (QFP) devices. As noted above, the readout system 150 may in some embodiments be partially arranged within the low temperature stage 101. For instance, the readout system 150 may comprise a room temperature computing device and/or a digital logic device coupled to a low temperature QFP circuit, which is configured to generate a digital signal based on an analog signal generated based on the state of the flux qubit 110.

In some embodiments, the readout system 150 comprises multiple inductively coupled devices that together generate a room temperature signal from low temperature electronics (e.g., QFP digital logic), which generate a signal based on the state of the flux qubit 110. As one example, the readout system 150 may comprise a quantum flux parametron (QFP) coupled to a DC superconducting quantum interference device (SQUID). In some embodiments, the readout system may comprise a resonator coupled to a feedline. For instance, a QFP circuit may be inductively coupled to a SQUID, which is connected in series with a quarter wave resonator, which is in turn capacitively coupled to a feedline. Any of these configurations for the readout system comprising flux-based superconducting digital logic, such as but not limited to QFP, may allow for classical electronics to measure the state of the flux qubit 110 inside the low temperature stage 101.

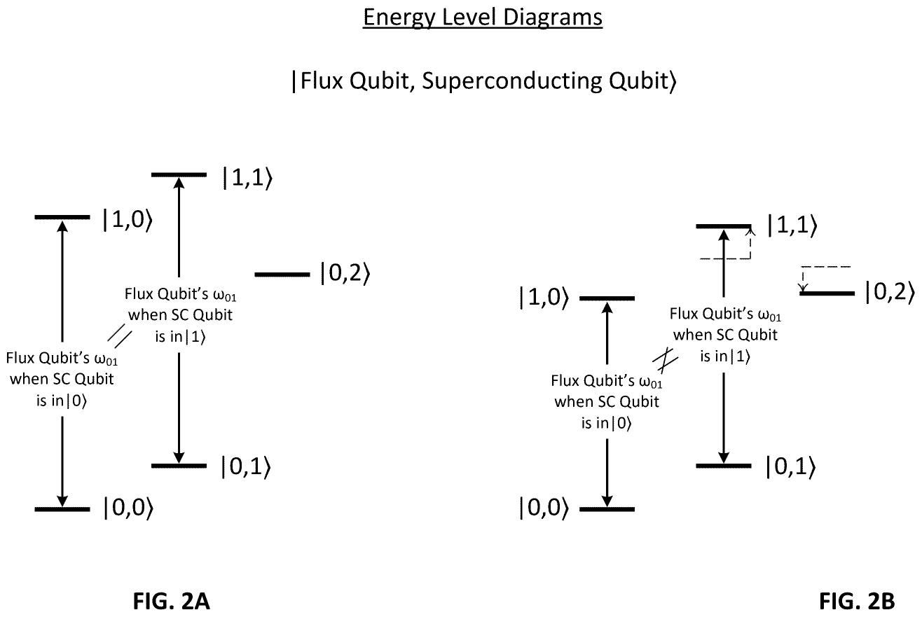

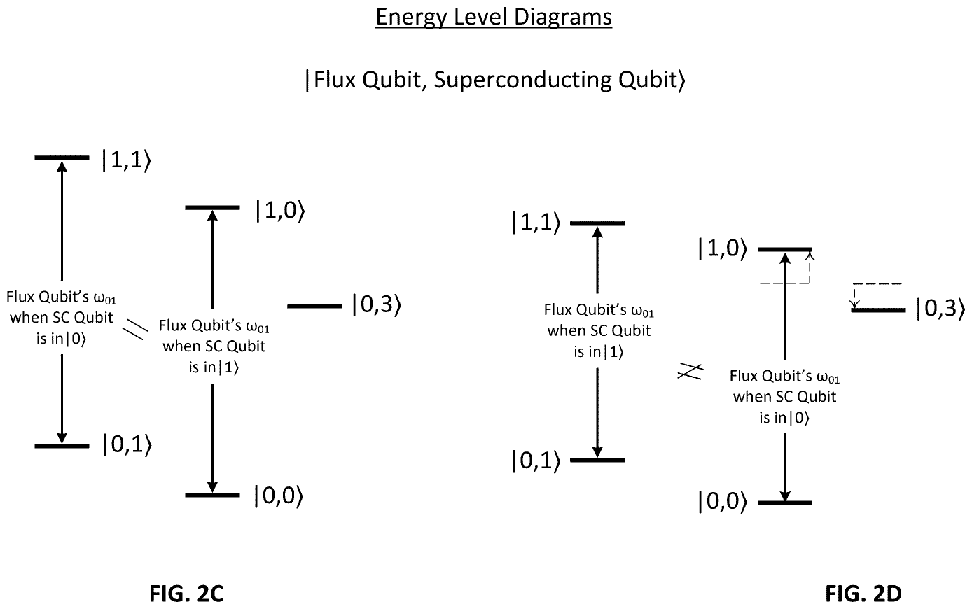

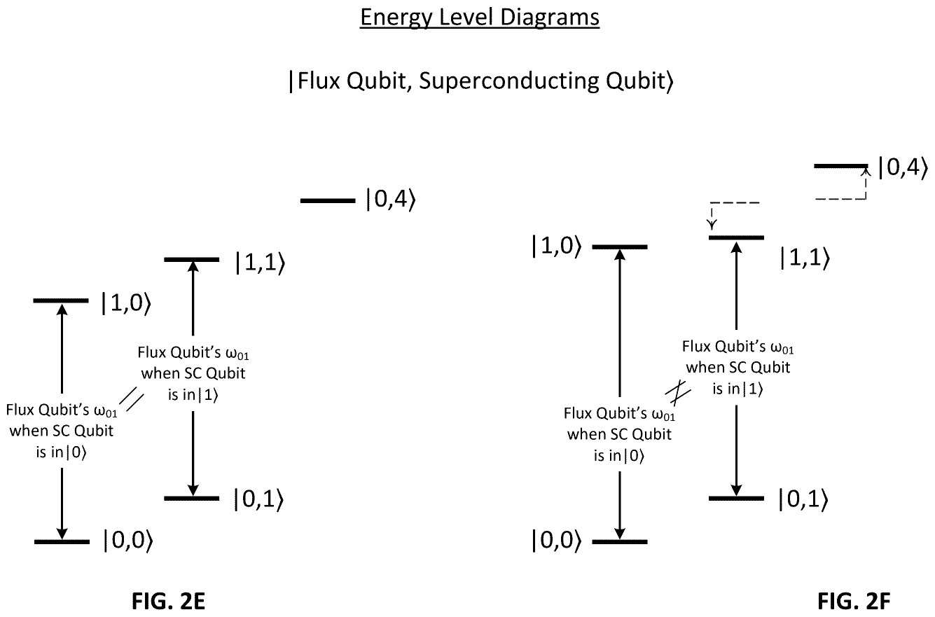

As described above, the flux bias of the flux qubit 110 may be controlled by the flux controller 130 to bring a frequency corresponding to a level transition of the flux qubit in, or out of, resonance with a transition frequency of a level transition of the superconducting qubit 120. When the flux qubit 110 is flux biased so that the transitions are resonant with one another (or sufficiency close to resonant to induce the desired effect, described below), the level transition of the flux qubit may be driven with microwave generator 140, which conditionally excites the flux qubit according to the state of the superconducting qubit 120. States of the flux qubit and superconducting qubit associated with this process are illustrated by the energy level diagrams shown in FIGS. 2A-2F, according to some embodiments.

In the example of FIGS. 2A-2B, the states |0 [symbol] and |1 [symbol] of a flux qubit (e.g., flux qubit 110) are considered, along with the states |0 [symbol] , |1 [symbol] and |2 [symbol] of a superconducting qubit (e.g., superconducting qubit 120) that is coupled to the flux qubit via a suitable coupler. The state of the combined flux qubit and superconducting qubit system is written in FIGS. 2A-2B as |F, Q [symbol] where |F [symbol] is the state of the flux qubit, and |Q [symbol] is the state of the superconducting qubit. Each of the energy levels in FIGS. 2A-2B therefore represents an energy level associated with a pair of the states of the flux qubit and the superconducting qubit.

Two different configurations of the flux qubit and superconducting qubit are depicted in FIG. 2A and in FIG. 2B. In the example of FIG. 2A, the flux qubit is flux biased so that the transition frequency ω01 of the transition between its |0 [symbol] and |1 [symbol] states is detuned from each of the transition frequencies associated with the |0 [symbol] ↔|1 [symbol] and |1 [symbol] ↔|2 [symbol] transitions of the superconducting qubit. In this configuration, the difference in energy ω₀₁ between the |0,0 [symbol] and |0,1 [symbol] states is the same as the difference in energy ω₀₁ between the |1,0 [symbol] and |1,1 [symbol] states. That is, the same frequency stimulates a transition of the flux qubit between its |0 [symbol] and |1 [symbol] states, irrespective of whether the superconducting qubit is in its |0 [symbol] or |1 [symbol] state. In this configuration, the superconducting qubit may be driven independently of the flux qubit, such as to perform a quantum circuit in which the state of the superconducting qubit is manipulated by a superconducting qubit controller (e.g., superconducting qubit controller 160).

To readout the quantum state of the superconducting qubit, the flux qubit is flux biased so that the transition between its |0 [symbol] or |1 [symbol] state is resonant, or close to resonant, with the transition between the |1 [symbol] and |2 [symbol] states of the superconducting qubit. When these two transitions are sufficiently resonant, the same drive frequency would in principle drive the transition |0 [symbol] ↔|1 [symbol] of the flux qubit as well as drive the |1 [symbol] ↔|2 [symbol] transition of the superconducting qubit. Writing this in the notation of FIGS. 2A and 2B, this means that transitions can be driven between the |0,2 [symbol] and |1,1 [symbol] states with a resonant drive frequency. Due to the phenomenon of level repulsion, however, this resonance causes the |0,2 [symbol] and |1,1 [symbol] states to change in energy, as shown by the dotted lines and arrows in FIG. 2B. In particular, the |1,1 [symbol] state increases to a higher energy, while the |0,2 [symbol] state decreases to a lower energy. As a result of this level repulsion, it is no longer true that the difference in energy ω₀₁ between the |0,0 [symbol] and |0,1 [symbol] states is the same as the difference in energy ω₀₁ between the |1,0 [symbol] and |1,1 [symbol] states. It may be noted that in some cases, the level repulsion might cause the |0,2 [symbol] state to increases to a higher energy and the |1,1 [symbol] state to decrease to a lower energy; in either case, the resulting energy levels allows for conditional driving of the flux qubit as described below.

The above process thereby allows conditional driving of the flux qubit, which effectively maps the state of the superconducting qubit onto the state of the flux qubit. In particular, by driving the flux qubit with a microwave pulse that is resonant with the |0,1 [symbol] to |1,1 [symbol] transition, this will cause the flux qubit to be excited to the |1 [symbol] state only if the superconducting qubit is in its |1 [symbol] state. Since the |0,0 [symbol] to |1,0 [symbol] transition now has a different transition frequency, that transition is not stimulated by this microwave pulse. The result of this process is that the microwave drive applied to the flux qubit once it is flux biased as described above will produce a |1 [symbol] state in the flux qubit when the superconducting qubit is in its |1 [symbol] state, and will produce a |0 [symbol] state in the flux qubit when the superconducting qubit is in its |0 [symbol] state, effectively mapping the superconducting qubit state onto the flux qubit state.

Alternatively, the flux qubit could be driven with a microwave pulse that is resonant with the |0,0 [symbol] to |1,0 [symbol] transition, which will cause the flux qubit to be excited to the |1 [symbol] state only if the superconducting qubit is in its |0 [symbol] state. Since the |1,0 [symbol] to |1,1 [symbol] transition has a different transition frequency, that transition is not stimulated by this microwave pulse. In this case, the microwave drive applied to the flux qubit once it is flux biased as described above will produce a |0 [symbol] state in the flux qubit when the superconducting qubit is in its |1 [symbol] state, and will produce a |1 [symbol] state in the flux qubit when the superconducting qubit is in its |0 [symbol] state. This is a different mapping to the one described in the previous paragraph, though one mapping may be preferred over the other mapping if, for example, there are parasitic modes present that are undesirable to drive, so that one drive frequency (and thereby mapping) can be chosen over the other to avoid driving such modes.

It may be noted that the above effect can be produced even when the |0,2 [symbol] and |1,1 [symbol] states would not have exactly the same energy in the absence of level repulsion. So long as the resonance is sufficiently strong to cause level repulsion between the |0,2 [symbol] and |1,1 [symbol] states in the example of FIG. 2B, and the level repulsion is sufficiently large that it is possible to drive one of the |0,0 [symbol] to |1,0 [symbol] or |0,1 [symbol] to |1,1 [symbol] transitions without driving the other transition. As such, any references to controlling a flux bias of a flux qubit such that a first transition frequency corresponding to a level transition of the flux qubit is resonant with a second transition frequency corresponding to a level transition of a superconducting qubit shall be understood to not require precise resonance between the level transition of the flux qubit and the level transition of a superconducting qubit. So long as the resonance produced by controlling the flux bias of a flux qubit is sufficient to produce level repulsion between states of the flux qubit and superconducting qubit that allows for conditional driving of the flux qubit, the transitions of the flux qubit and the superconducting qubit are considered to be “resonant” for the purposes of this disclosure. As one example, the detuning between the |0,2 [symbol] and |1,1 [symbol] states may be less than the coupling strength between the |0,2 [symbol] and |1,1 [symbol] states.

Furthermore, additional resonances between different states might also be considered, and the flux qubit may be flux biased so that the transition between its |0 [symbol] and |1 [symbol] states is resonant, or close to resonant, with a different transition between states of the superconducting qubit (i.e., other than the transition between the |1 [symbol] and |2 [symbol] states of the superconducting qubit as described above). As examples, the flux qubit may be flux biased so that the transition between its |0 [symbol] and |1 [symbol] states is resonant, or close to resonant, with the transition between the |0 [symbol] and |3 [symbol] states of the superconducting qubit, or the flux qubit may be flux biased so that the transition between its |0 [symbol] and |1 [symbol] states is resonant, or close to resonant, with the transition between the |1 [symbol] and |4 [symbol] states of the superconducting qubit. FIGS. 2C-2D depict the first of these examples, which produces level repulsion between the |1,0 [symbol] and |0,3 [symbol] states, causing the transition frequency ω₀₁ of the flux qubit to be different when the superconducting qubit is in the |0 [symbol] state. FIGS. 2E-2F depict the second of these examples, which produces level repulsion between the |1,1 [symbol] and |0,4 [symbol] states, causing the transition frequency ω₀₁ of the flux qubit to be different when the superconducting qubit is in the |1 [symbol] state.

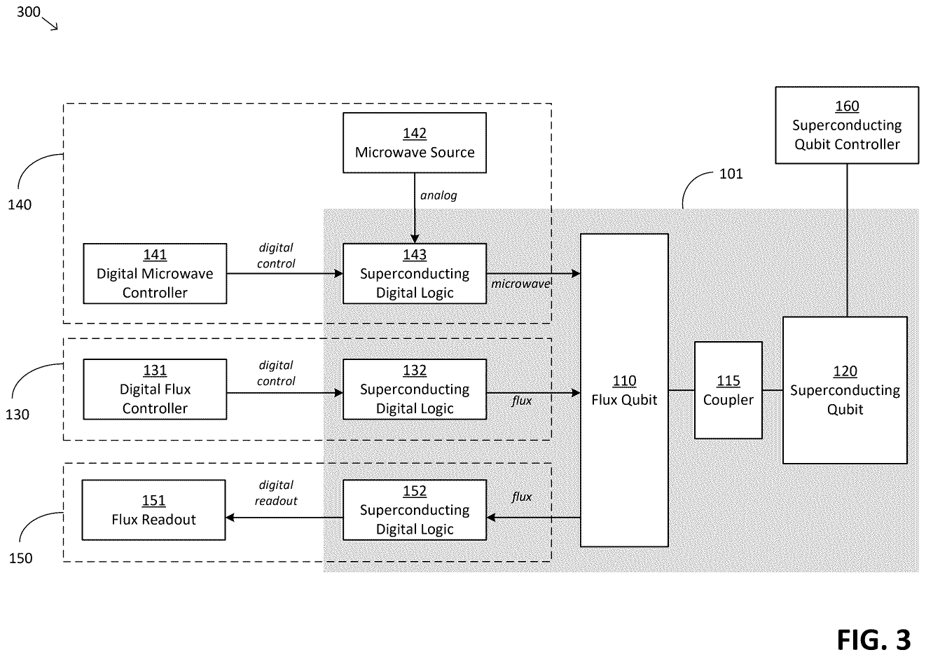

FIG. 3 is an illustrative implementation of the system of FIG. 1, according to some embodiments. In the example of FIG. 3, system 300 comprises the flux controller 130, microwave generator 140, and readout system 150 implemented using the depicted components. In particular, the flux controller 130 is implemented with a digital flux controller 131, and superconducting digital logic 132 which is arranged within the low temperature stage 101; the microwave generator 140 is implemented with a digital microwave controller 141, a microwave source 142, and superconducting digital logic 143 which is arranged within the low temperature stage 101; and the readout system 150 is implemented with flux readout 151, and superconducting digital logic 152 which is arranged within the low temperature stage 101. In some embodiments, the digital microwave controller 141 may also be arranged within the low temperature stage 101.

The superconducting digital logic 132, 143 and 152 may be implemented in a number of ways as described above in relation to flux controller 130, microwave generator 140, and readout system 150. For instance, any one or more of the superconducting digital logic 132, 143 and 152 may be implemented with AQFP-based digital logic. As shown in the example of FIG. 3, the digital microwave controller 141 and the digital flux controller 131 are configured to provide digital data to the superconducting digital logic 132 and 143, respectively, which generate an analog flux bias signal and an analog microwave signal, respectively, based on the received digital data. Similarly, in the example of FIG. 3 the superconducting digital logic 152 is configured to generate a measurement of the flux qubit 110 and produce a digital readout signal, which is provided to the flux readout 151.

In some embodiments, at least some aspects of any one or more of the digital microwave controller 141, digital flux controller 131, and flux readout 151 may be implemented together within a single digital signal interface. For instance, a general purpose computing system executing software may generate digital data for control of the superconducting digital logic 132 and 143, and may receive digital readout from the superconducting digital logic 152. Alternatively, each of the digital microwave controller 141, digital flux controller 131, and flux readout 151 may be implemented using hardware (e.g., one or more FPGAs), which may be collectively programmed and controlled by a general purpose computing system. In either case, hardware and/or software components may be configured to generate digital data by the digital microwave controller 141 and digital flux controller 131 in response to digital data generated or otherwise obtained by the flux readout 151.

In some embodiments, the superconducting digital logic 132, 143 and 152 may be operated with a common clock signal, such that readout of the flux qubit can be precisely timed along with operations to flux bias or drive the flux qubit with a microwave pulse.

According to some embodiments, the microwave source may generate a microwave signal having a single frequency, and the digital microwave controller 141 and/or superconducting digital logic 143 may be configured to generate a microwave signal to drive the flux qubit from this single frequency microwave signal. In some cases, the digital microwave controller 141 and/or superconducting digital logic 143 may be configured to adjust the frequency of the microwave carrier signal and/or modulate the microwave carrier signal to generate a microwave signal to drive a flux qubit. Where system 300 includes multiple qubit modules that each comprise a flux qubit, coupler and superconducting qubit, the same microwave source 142 may be used to drive the flux qubit in each qubit module, and the digital microwave controller 141 and/or superconducting digital logic 143 may be configured to adjust the frequency of the microwave carrier signal and/or modulate the microwave carrier signal for any given flux qubit in the qubit modules to generate a microwave signal to drive that flux qubit. In this manner, different flux qubits may be driven with microwave pulses in different ways, but by using a single microwave source.

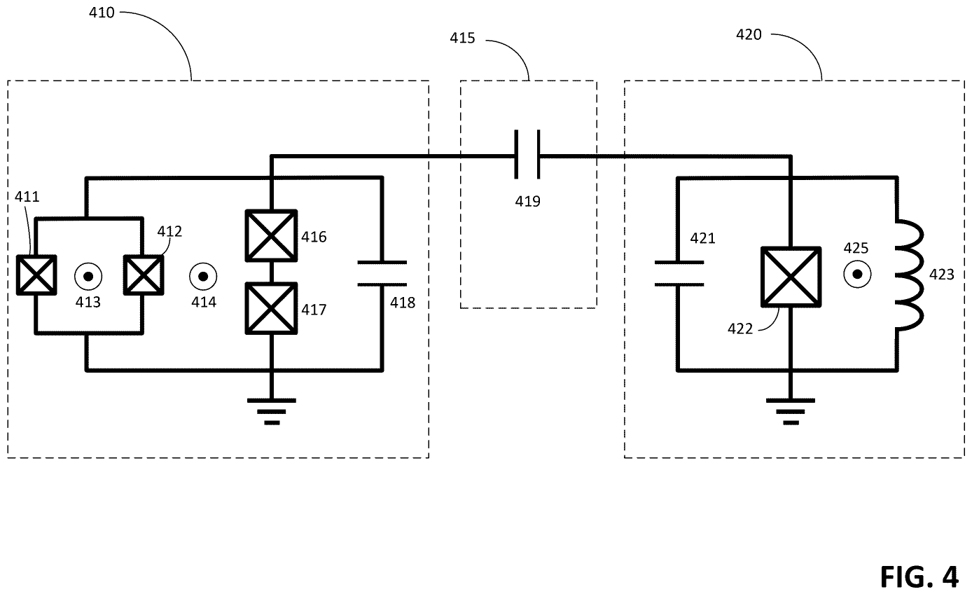

FIG. 4 depicts an illustrative implementation of a flux qubit, coupler and superconducting qubit, according to some embodiments. In the example of FIG. 4, a flux qubit (e.g., flux qubit 110) is implemented as a capacitively shunted flux qubit (CSFQ) 410, a coupler (e.g., coupler 115) is implemented as coupler 415, and a superconducting qubit (e.g., superconducting qubit 120) is implemented as a fluxonium qubit 420.

In the example of FIG. 4, the CSFQ 410 comprises a superconducting loop with a capacitor 418 in parallel with: i) a pair of Josephson junctions 416 and 417 and (ii) Josephson junctions 411 and 412, themselves arranged in parallel with one another. Magnetic flux bias 413 is threaded through the superconducting loop that includes the Josephson junctions 411 and 412, and a second magnetic flux bias 414 is threaded through the larger superconducting loop as shown. Each of magnetic flux bias 413 and magnetic flux bias 414 may be independently controlled by a suitable flux controller (such as flux controller 130) which generates a flux bias signal in flux bias lines that are each inductively coupled one of the two superconducting loops, as described above. In addition, the CSFQ 410 may be driven by a suitable microwave controller (such as microwave generator 140) which generates a microwave signal in drive lines that are capacitively coupled to the CSFQ 410.

In the example of FIG. 4, the coupler 415 comprises a capacitor 419 that capacitively couples the CSFQ 410 to the fluxonium qubit 420.

In the example of FIG. 4, the fluxonium qubit 420 comprises a superconducting loop with a capacitor 421, a Josephson junction 422, and an inductor 423 arranged in parallel with one another. A flux bias 425 is threaded through the superconducting loop, and may be independently controlled by a suitable flux controller (such as flux controller 130) which generates a flux bias signal in flux bias lines that are inductively coupled to each loop, as described above. In addition, the fluxonium qubit 420 may be driven by a suitable microwave controller (such as microwave generator 140) which generates a microwave signal in drive lines that are capacitively coupled to the fluxonium qubit 420.

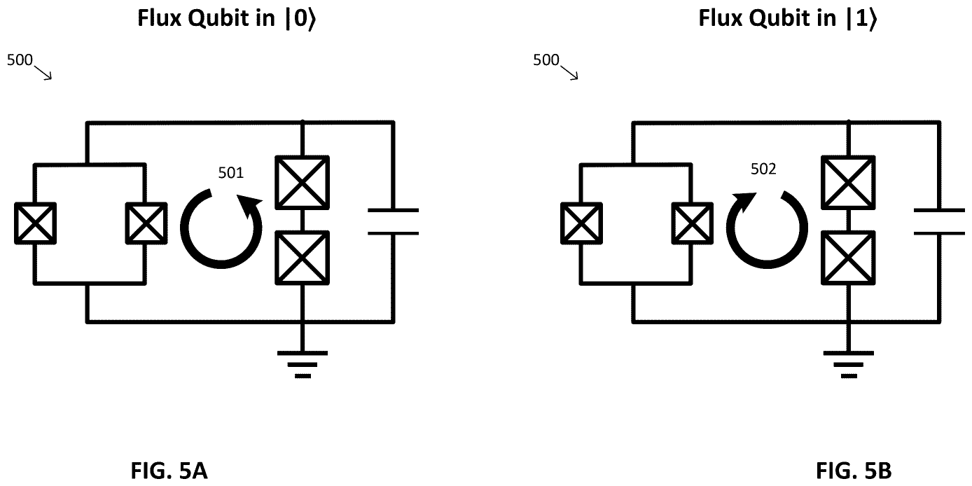

FIGS. 5A-5B depict an illustrative current that may flow through a capacitively shunted flux qubit, according to some embodiments. As described above, the state of a flux qubit may be measured in some cases by measuring a persistent current in the flux qubit, which has one or more properties that depends on its state. In the example of FIGS. 5A-5B, the flux bias(es) of the CSFQ 500 may be controlled to produce a persistent current that has a sign (direction) that is dependent on the state of the CSFQ. For instance, controlling the flux bias 413 and/or 414 may produce a persistent current 501 that circulates in a first direction when the CSFQ is in the |0 [symbol] state (as shown in FIG. 5A), or a persistent current 502 that circulates in a second direction, opposite to the first direction, when the CSFQ is in the |1 [symbol] state (as shown in FIG. 5B).

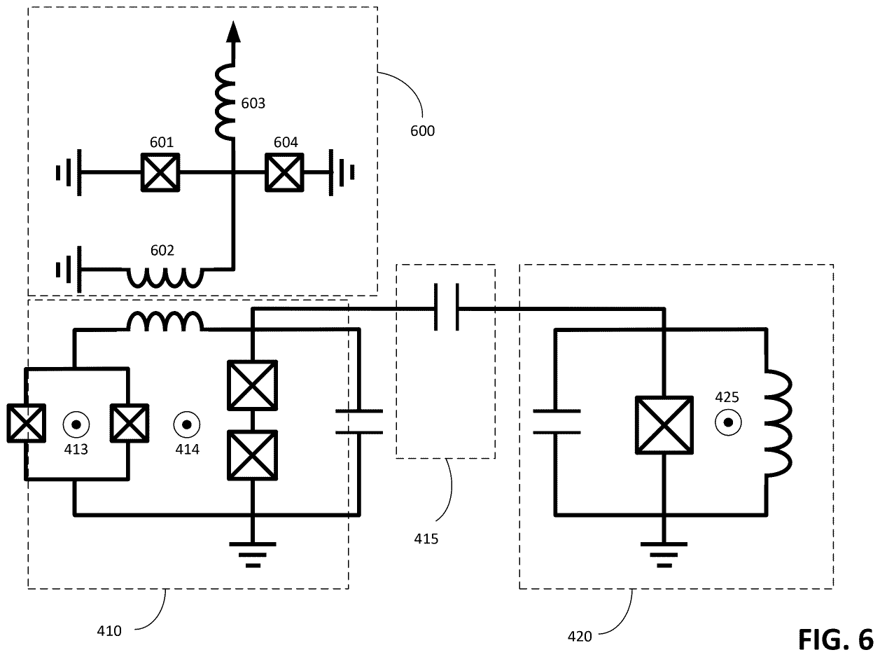

An illustrative way in which a persistent current in the flux qubit may be measured is depicted in FIG. 6, according to some embodiments. In the example of FIG. 6, the CSFQ 410, coupler 415 and fluxonium qubit 420 shown in FIG. 4 are depicted, wherein the CSFQ is coupled to a quantum flux parametron (QFP) circuit 600. In the example of FIG. 6, the QFP 600 includes Josephson junctions 601 and 604, and inductors 602 and 603, and is configured to perform a flux-based readout of the CSFQ 410, and to produce a digital readout signal.

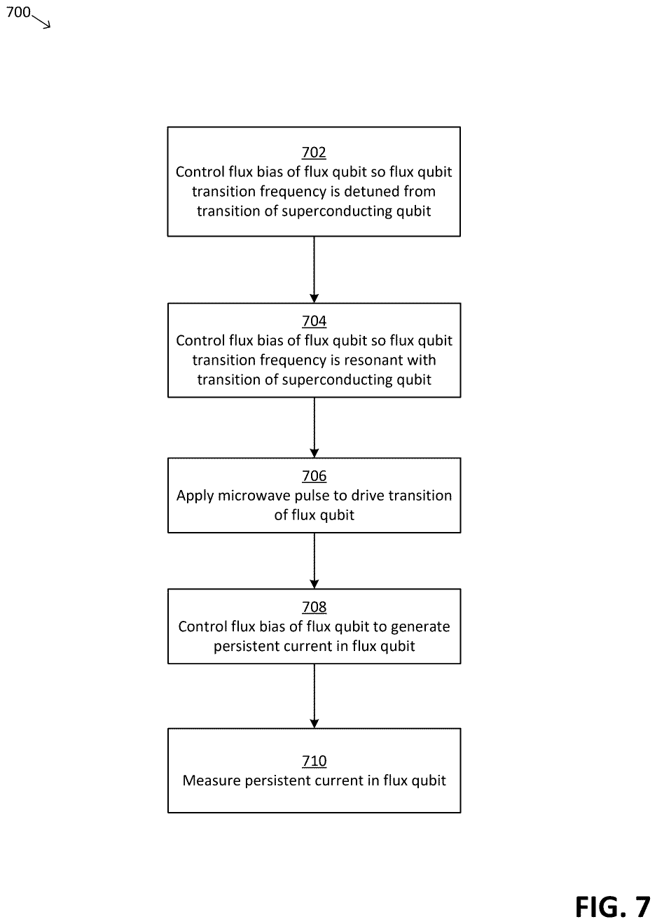

FIG. 7 is a flowchart of a method of performing flux-based readout of a superconducting qubit, according to some embodiments. Method 700 may be performed by a suitable system comprising a flux qubit coupled to a superconducting qubit via a coupler, and configured to control the flux bias of the flux qubit, apply microwave pulses to the flux qubit, and measure a persistent current in the flux qubit. For example, each of system 100 shown in FIG. 1, and system 300 shown in FIG. 3, may perform method 700.

In act 702, the system performing method 700 controls the flux bias of the flux qubit so that one or more transition frequencies of transitions between states of the flux qubit are detuned from one or more transition frequencies of transitions of the superconducting qubit. One example of this tuning is shown in FIG. 2A, in which the flux bias of a flux qubit is controlled so that the transition between its |0 [symbol] and |1 [symbol] states is detuned from each of the transitions between the |0 [symbol] and |1 [symbol] states, and between the |1 [symbol] and |2 [symbol] states, of the superconducting qubit.

In some embodiments, act 702 comprises generating an analog flux bias signal and supplying this signal to the flux qubit. Examples of suitable hardware for generating such a signal are described above, and any of these may be operated as described above in act 702. For example, act 702 may comprise operating a low temperature AQFP circuit based on digital data supplied to the AQFP circuit to generate one or more analog flux bias signals (e.g., one signal for each flux bias of the flux qubit).

In some embodiments, act 702 comprises controlling multiple flux bias signals to the flux qubit. For instance, the illustrative CSFQs shown in FIGS. 4 and 6 each has multiple different magnetic fluxes that are threaded through different superconducting loops. Either or both of these fluxes may be controlled in act 702. In some embodiments, act 702 comprises controlling either or both of two flux biases of the flux qubit (e.g., flux bias 413 and flux bias 414 shown in FIG. 4) to zero. This may produce a persistent current of zero, or close to zero, in the flux qubit.

According to some embodiments, the superconducting qubit is a fluxonium qubit and the flux bias of the fluxonium qubit may be controlled, in act 702 or at least prior to act 704, to be a half-integer multiple of the magnetic flux quantum. That is, the flux bias of the fluxonium qubit (e.g., the flux bias 425 shown in FIG. 4) is controlled to be equal to

$${Φ}_{ext} = ( \frac{2 n + 1}{2} ) {Φ}_{0} ,$$

where n is an integer and

$${Φ}_{0} + \frac{h}{2 e}$$

is the magnetic flux quantum, where h is Planck's constant and e is the charge of an electron. For example, the flux bias of the fluxonium qubit may be controlled to be

$${Φ}_{ext} = \frac{1}{2} {Φ}_{0} or {Φ}_{ext} = \frac{3}{2} {Φ}_{0} ,$$

etc.

In act 704, the system performing method 700 controls the flux bias (or biases) of the flux qubit so that the transition frequency of a transition between states of the flux qubit is near resonant with a transition frequency of a transition of the superconducting qubit. With respect to the example of FIG. 4, for instance, the flux bias 413 and flux bias 414 shown in FIG. 4 may both be controlled to produce a resonance between transitions of the flux qubit and the superconducting qubit. One example of such a resonant tuning is shown in FIG. 2B, in which one or more flux biases of a flux qubit are controlled so that the transition between its |0 [symbol] and |1 [symbol] states is resonant with the transition between the |1 [symbol] and |2 [symbol] states of the superconducting qubit. However, other tunings may also be envisioned so that two transition frequencies (one of the flux qubit, and one of the superconducting qubit) are resonant. For instance, where the superconducting qubit is a fluxonium qubit, the transition frequency of the transition between the |0 [symbol] and |1 [symbol] states of the flux qubit may be tuned to be resonant with the transition frequency of the transition between the |0 [symbol] and |3 [symbol] states of the fluxonium qubit; or the transition frequency of the transition between the |0 [symbol] and |1 [symbol] states of the flux qubit may be tuned to be resonant with the transition frequency of the transition between the |1 [symbol] and |4 [symbol] states of the fluxonium qubit.

Examples of suitable hardware for generating a flux bias signal are described above, and any of these may be operated as described above in act 704. For example, act 704 may comprise operating a low temperature AQFP circuit based on digital data supplied to the AQFP circuit to generate one or more analog flux bias signals (e.g., one signal for each flux bias of the flux qubit) that are directed to the flux qubit via flux bias lines that are each inductively coupled to a superconducting loop of the flux qubit.

In act 706, the system performing method 700 applies one or more microwave pulses to the flux qubit to drive a transition of the flux qubit. For example, as described above with respect to the example of FIGS. 2A-2B, the transition between the |0 [symbol] and |1 [symbol] states may be tuned to be resonant with the transition between the |1 [symbol] and |2 [symbol] states of the superconducting qubit. Subsequently, one or more microwave pulses may be applied to the flux qubit to drive the transition between the |0 [symbol] and |1 [symbol] states when the superconducting qubit is in the |1 [symbol] state. Alternatively, one or more microwave pulses may be applied to the flux qubit to drive the transition between the |0 [symbol] and |1 [symbol] states when the superconducting qubit is in the |0 [symbol] state. In either case, the microwave pulse(s) drive the flux qubit so that it will be either excited or not excited, depending on the state of the superconducting qubit. Examples of suitable hardware for generating microwave pulses are described above, and any of these may be operated as described above in act 706. For example, act 706 may comprise operating a low temperature AQFP circuit based on digital data supplied to the AQFP circuit to generate one or more analog microwave pulses.

In act 708, the system performing method 700 controls the flux bias (or biases) of the flux qubit to switch on its persistent current. Generally, this comprises increasing the flux bias(es) of the flux qubit compared with the flux bias(es) set in act 704. As one example, the flux bias 413 and flux bias 414 shown in FIG. 4 may both be controlled so that the flux bias 413 is

$${Φ}_{x}^{CSFQ} = 1 {Φ}_{0}$$

and the flux bias 414 is

$${Φ}_{z}^{CSFQ}$$

is on the order of mΦ₀. Examples of suitable hardware for generating such a signal are described above, and any of these may be operated as described above in act 708. For example, act 708 may comprise operating a low temperature AQFP circuit based on digital data supplied to the AQFP circuit to generate one or more analog flux bias signals (e.g., one signal for each flux bias of the flux qubit) that are directed to the flux qubit via flux bias lines that are each inductively coupled to a superconducting loop of the flux qubit (e.g., one flux bias line inductively coupled to the loop through which flux 413 is threaded, and one flux bias line inductively coupled to the loop through which flux 414 is threaded). Act 708 may in some instances produce a persistent current within the flux qubit that has a direction that depends on the state of the flux qubit, as shown in FIGS. 5A-5B.

In act 710, the system performing method 700 measures the persistent current in the flux qubit that was switched on in act 708. In some embodiments, act 710 may comprise operating a readout system (e.g., readout system 150 shown in FIG. 1) to measure the persistent current using a flux-sensitive element, such as a QFP. In some cases, act 710 comprises inducing a current in such a flux-sensitive element from the persistent current in the flux qubit. For example, a current in a QFP inductively coupled to the flux qubit may be generated in act 710, with a direction of the current induced in the QFP being dependent on the direction of the persistent current in the flux qubit (and thereby the state of the flux qubit). In some embodiments, a digital signal may be produced in act 710 that indicates the state of the flux qubit (e.g., in each clock cycle), which is indicative of the state of the superconducting qubit. For instance, a QFP may produce such a digital signal based on a direction of current induced in the QFP.

Subsequent to act 710, act 702 may be performed again to control the flux qubit to be in an idle state.

As referred to herein, a “qubit” includes any multi-level quantum-mechanical system capable of being controlled by a quantum information processor. The quantum states of the qubit may for instance include electronic states, polarization states, vibrational states, rotational states, or spin states. As referred to herein, a “superconducting qubit” includes any superconducting electronic circuit that may be operated as a multi-level quantum-mechanical system, such as a charge qubit (e.g., a transmon), a flux qubit (e.g., a fluxonium qubit), or a phase qubit.

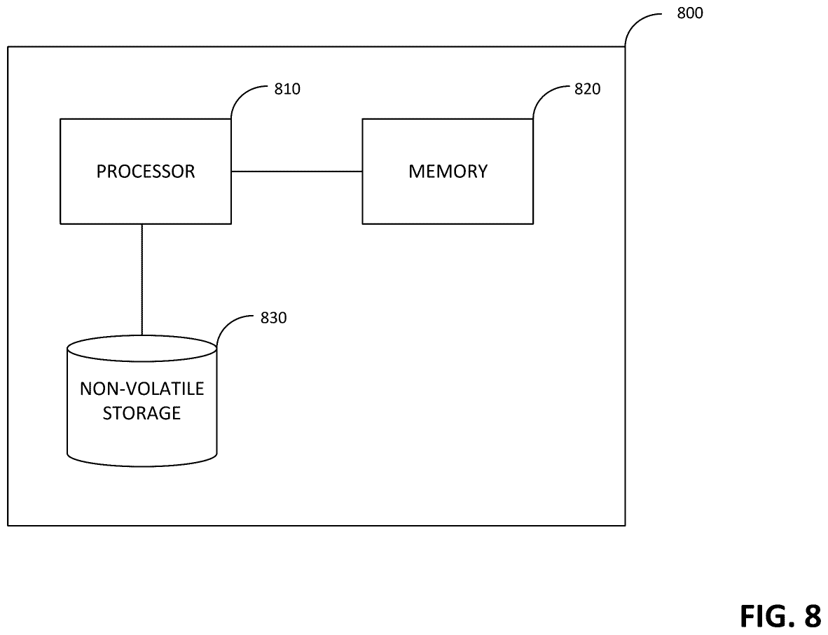

An illustrative implementation of a computer system 800 that may be used to control a flux controller, microwave generator, readout system and/or superconducting qubit controller to perform any of the techniques described above is shown in FIG. 8. The computer system 800 may include one or more processors 810 and one or more non-transitory computer-readable storage media (e.g., memory 820 and one or more non-volatile storage media 830). The one or more processors 810 may control writing data to and reading data from the memory 820 and the one or more non-volatile storage media 830 in any suitable manner, as the aspects of the disclosure described herein are not limited in this respect. To perform functionality and/or techniques described herein, the one or more processors 810 may execute one or more instructions stored in one or more computer-readable storage media (e.g., the memory 820, storage media, etc.), which may serve as non-transitory computer-readable storage media storing instructions for execution by the one or more processors 810.

In connection with techniques described herein, code used to, for example, generate digital data to control generation of a flux bias signal or a microwave pulse, etc. may be stored on one or more computer-readable storage media of computer system 800. The one or more processors 810 may execute any such code to perform any of the above-described techniques as described herein. Any other software, programs or instructions described herein may also be stored and executed by computer system 800. It will be appreciated that computer code may be applied to any aspects of methods and techniques described herein. For example, computer code may be applied to generate digital data to control generation of a flux bias signal or a microwave pulse in response to digital data obtained from reading the state of a flux qubit, etc.

The various methods or processes outlined herein may be coded as software that is executable on one or more processors that employ any one of a variety of operating systems or platforms. Additionally, such software may be written using any of numerous suitable programming languages and/or programming or scripting tools, and also may be compiled as executable machine language code or intermediate code that is executed on a virtual machine or a suitable framework.

In this respect, various inventive concepts may be embodied as at least one non-transitory computer readable storage medium (e.g., a computer memory, one or more floppy discs, compact discs, optical discs, magnetic tapes, flash memories, circuit configurations in Field Programmable Gate Arrays or other semiconductor devices, etc.) encoded with one or more programs that, when executed on one or more computers or other processors, implement the various embodiments of the present disclosure. The non-transitory computer-readable medium or media may be transportable, such that the program or programs stored thereon may be loaded onto any computer resource to implement various aspects of the present disclosure as described above.

The terms “program,” “software,” and/or “application” are used herein in a generic sense to refer to any type of computer code or set of computer-executable instructions that can be employed to program a computer or other processor to implement various aspects of embodiments as described above. Additionally, it should be appreciated that according to one aspect, one or more computer programs that when executed perform methods of the present disclosure need not reside on a single computer or processor, but may be distributed in a modular fashion among different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in non-transitory computer-readable storage media in any suitable form. Data structures may have fields that are related through location in the data structure. Such relationships may likewise be achieved by assigning storage for the fields with locations in a non-transitory computer-readable medium that convey relationship between the fields. However, any suitable mechanism may be used to establish relationships among information in fields of a data structure, including through the use of pointers, tags or other mechanisms that establish relationships among data elements.

Having thus described several aspects of at least one embodiment of this disclosure, it is to be appreciated that various alterations, modifications, and improvements will readily occur to those skilled in the art. For instance, aspects of the techniques described herein may be combined in any of the following ways:

Aspect 1. A system comprising: a superconducting qubit; a flux qubit coupled to the superconducting qubit via a coupling element; and a readout system coupled to the flux qubit and configured to measure a current in the flux qubit that is indicative of a quantum state of the superconducting qubit.

Aspect 2. The system of aspect 1, further comprising a superconducting qubit controller configured to control the quantum state of the superconducting qubit.

Aspect 3. The system of aspect 1, further comprising a flux controller configured to control a flux bias of the flux qubit such that a first transition frequency corresponding to a level transition of the flux qubit is resonant with a second transition frequency corresponding to a level transition of the superconducting qubit.

Aspect 4. The system of aspect 3, wherein the level transition of the flux qubit is a transition between |0 [symbol] and |1 [symbol] states of the flux qubit, and wherein the level transition of the superconducting qubit is a transition between |1 [symbol] and |2 [symbol] states of the superconducting qubit.

Aspect 5. The system of aspect 3, wherein the level transition of the flux qubit is a transition between |0 [symbol] and |1 [symbol] states of the flux qubit, and wherein the level transition of the superconducting qubit is a transition between |0 [symbol] and |3 [symbol] states of the superconducting qubit.

Aspect 6. The system of aspect 3, wherein the level transition of the flux qubit is a transition between |0 [symbol] and |1 [symbol] states of the flux qubit, and wherein the level transition of the superconducting qubit is a transition between |1 [symbol] and |4 [symbol] states of the superconducting qubit.

Aspect 7. The system of aspect 3, further comprising a microwave generator configured to apply at least one microwave pulse to the flux qubit that drives the level transition of the flux qubit.

Aspect 8. The system of aspect 7, wherein the microwave generator comprises one or more drive lines that are capacitively coupled to the flux qubit, and wherein the microwave generator is configured to apply the at least one microwave pulse to the flux qubit through the one or more drive lines.

Aspect 9. The system of aspect 7, wherein the microwave generator is configured to apply the at least one microwave pulse to the flux qubit subsequent to the flux controller flux biasing the flux qubit such that that the first transition frequency is resonant with the second transition frequency.

Aspect 10. The system of aspect 7, wherein the flux controller is further configured to control the flux bias of the flux qubit to generate the current in the flux qubit that is indicative of the quantum state of the superconducting qubit.

Aspect 11. The system of aspect 10, wherein the flux controller is configured to control the flux bias of the flux qubit to generate the current in the flux qubit that is indicative of the quantum state of the superconducting qubit subsequent to the microwave generator applying the at least one microwave pulse to the flux qubit that drives the level transition of the flux qubit.

Aspect 12. The system of aspect 3, wherein the flux bias of the flux qubit comprises at least two components.

Aspect 13. The system of aspect 1, wherein the readout system comprises a superconducting circuit configured to generate a signal corresponding to the current measured in the flux qubit.

Aspect 14. The system of aspect 13, wherein the superconducting circuit comprises a single flux quantum (SFQ) circuit, an adiabatic quantum flux parametron (AQFP) circuit or a quantum flux parametron (QFP) circuit.

Aspect 15. The system of aspect 14, wherein the superconducting circuit comprises a quantum flux parametron (QFP) circuit inductively coupled to the flux qubit.

Aspect 16. The system of aspect 3, wherein the flux controller comprises a superconducting digital logic device configured to control the flux bias of the flux qubit based on one or more digital values.

Aspect 17. The system of aspect 7, wherein the microwave generator comprises a superconducting digital logic device configured to produce the at least one microwave pulse based on one or more digital values.

Aspect 18. The system of aspect 17, wherein the microwave generator comprises a microwave source configured to produce a microwave signal, and wherein the superconducting digital logic device is further configured to control switching of the microwave signal to generate the at least one microwave pulse.

Aspect 19. The system of aspect 1, wherein the coupling element is a capacitor, an inductor, a tunable coupler, a dual mode coupler, or a fluxonium qubit.

Aspect 20. The system of aspect 1, wherein the flux qubit is a capacitively shunted flux qubit.

Aspect 21. The system of aspect 1, wherein the superconducting qubit is a fluxonium qubit.

Aspect 22. A method comprising: controlling a flux bias of a flux qubit such that a first transition frequency corresponding to a level transition of the flux qubit is resonant with a second transition frequency corresponding to a level transition of a superconducting qubit, the superconducting qubit being coupled to the flux qubit via a coupling element; applying at least one microwave pulse to the flux qubit that drives the level transition of the flux qubit; controlling the flux bias of the flux qubit to generate a persistent current in the flux qubit; and measuring the persistent current in the flux qubit using a readout system.

Aspect 23. The method of aspect 22, further comprising, prior to controlling the flux bias of the flux qubit such that the first transition frequency is resonant with the second transition frequency, operating a superconducting qubit controller to perform at least one single-qubit gate on the superconducting qubit.

Aspect 24. The method of aspect 22, wherein the level transition of the flux qubit is a transition between |0 [symbol] and |1 [symbol] states of the flux qubit, and wherein the level transition of the superconducting qubit is a transition between |1 [symbol] and |2 [symbol] states of the superconducting qubit.

Aspect 25. The method of aspect 22, further comprising measuring a quantum state of the superconducting qubit based on the persistent current measured in the flux qubit.

Aspect 26. The method of aspect 22, further comprising, prior to controlling the flux bias of the flux qubit such that the first transition frequency is resonant with the second transition frequency, controlling the flux bias of the flux qubit so that the first transition frequency is detuned from the second transition frequency.

Aspect 27. The method of aspect 22, wherein controlling the flux bias of the flux qubit so that the first transition frequency is detuned from the second transition frequency comprises setting the flux bias of the flux qubit to zero.

Aspect 28. The method of aspect 22, wherein measuring the persistent current in the flux qubit comprises measuring a direction of current flowing in the flux qubit.

Aspect 29. The method of aspect 22, wherein measuring the persistent current in the flux qubit comprises generating a current in a superconducting circuit inductively coupled to the flux qubit.

Aspect 30. The method of aspect 29, wherein measuring the persistent current in the flux qubit further comprises generating a digital signal corresponding to a direction of the current generated in the superconducting circuit.

Aspect 31. The method of aspect 29, wherein the superconducting circuit comprises an adiabatic quantum flux parametron (AQFP) circuit or a quantum flux parametron (QFP) circuit.

Aspect 32. The method of aspect 22, comprising applying the at least one microwave pulse to the flux qubit that drives the level transition of the flux qubit according to one or more digital values.

Aspect 33. The method of aspect 22, wherein the coupling element is a capacitor, an inductor, a tunable coupler, a dual mode coupler, or a fluxonium qubit.

Aspect 34. The method of aspect 22, wherein the flux qubit is a capacitively shunted flux qubit.

Aspect 35. The method of aspect 22, wherein the superconducting qubit is a fluxonium qubit.

Aspect 36. The method of aspect 22, wherein the flux qubit is a first flux qubit, wherein the superconducting qubit is a first superconducting qubit, wherein the coupling element is a first coupling element, wherein the at least one microwave pulse comprises a first microwave pulse and wherein the method further comprises: generating the first microwave pulse from a microwave source having a single carrier frequency; generating a second microwave pulse from the microwave source having the single carrier frequency; controlling a flux bias of a second flux qubit such that a first transition frequency corresponding to a level transition of the second flux qubit is resonant with a second transition frequency corresponding to a level transition of a second superconducting qubit, the second superconducting qubit being coupled to the second flux qubit via a second coupling element; and applying the second microwave pulse to the second flux qubit that drives the level transition of the second flux qubit.

Aspect 37. A system comprising: a plurality of qubit modules, each qubit module comprising: a superconducting qubit; a coupling element; and a flux qubit coupled to the superconducting qubit via a coupling element; and a readout system coupled to the flux qubit in each of the plurality of qubit modules, and configured to measure a current in the flux qubit in a respective qubit module that is indicative of a quantum state of the superconducting qubit to which the flux qubit in the respective qubit module is coupled.

Aspect 38. The system of aspect 37, further comprising a microwave generator configured to apply at least one microwave pulse to the flux qubit in the respective qubit module, to drive a level transition of the flux qubit in the respective qubit module.

Aspect 39. The system of aspect 38, wherein the microwave generator comprises a microwave source having a single carrier frequency and is configured to generate the at least one microwave pulse to be applied to the flux qubit in each of the plurality of qubit modules from the microwave source having the single carrier frequency.

Such alterations, modifications, and improvements are intended to be part of this disclosure and are intended to be within the spirit and scope of the disclosure. Further, though advantages of the present disclosure are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

Aspects of the above-described embodiments of the technology described herein can be implemented in any of numerous ways. For example, aspects of the embodiments may be implemented using hardware, software, or a combination thereof. When implemented in software, the software code can be executed on any suitable processor or collection of processors, whether provided in a single computer or distributed among multiple computers. Such processors may be implemented as integrated circuits, with one or more processors in an integrated circuit component, including commercially available integrated circuit components known in the art by names such as CPU chips, GPU chips, microprocessor, microcontroller, or co-processor. Alternatively, a processor may be implemented in custom circuitry, such as an ASIC, or semi-custom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores such that one or a subset of those cores may constitute a processor. Though, a processor may be implemented using circuitry in any suitable format.

Various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, aspects of the disclosure may be embodied as a method, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A system comprising:
a superconducting qubit;
a flux qubit coupled to the superconducting qubit via a coupling element; and
a readout system coupled to the flux qubit and configured to measure a current in the flux qubit that is indicative of a quantum state of the superconducting qubit.

2. The system of claim 1, further comprising a flux controller configured to control a flux bias of the flux qubit such that a first transition frequency corresponding to a level transition of the flux qubit is resonant with a second transition frequency corresponding to a level transition of the superconducting qubit.

3. The system of claim 2, wherein the level transition of the flux qubit is a transition between |0 [symbol] and |1 [symbol] states of the flux qubit, and wherein the level transition of the superconducting qubit is a transition between |1 [symbol] and |2 [symbol] states of the superconducting qubit.

4. The system of claim 2, further comprising a microwave generator configured to apply at least one microwave pulse to the flux qubit that drives the level transition of the flux qubit.

5. The system of claim 4, wherein the microwave generator is configured to apply the at least one microwave pulse to the flux qubit subsequent to the flux controller flux biasing the flux qubit such that that the first transition frequency is resonant with the second transition frequency.

6. The system of claim 4, wherein the flux controller is further configured to control the flux bias of the flux qubit to generate the current in the flux qubit that is indicative of the quantum state of the superconducting qubit.

7. The system of claim 6, wherein the flux controller is configured to control the flux bias of the flux qubit to generate the current in the flux qubit that is indicative of the quantum state of the superconducting qubit subsequent to the microwave generator applying the at least one microwave pulse to the flux qubit that drives the level transition of the flux qubit.

8. The system of claim 1, wherein the readout system comprises a superconducting circuit configured to generate a signal corresponding to the current measured in the flux qubit.

9. The system of claim 8, wherein the superconducting circuit comprises a single flux quantum (SFQ) circuit or a quantum flux parametron (QFP) circuit.

10. The system of claim 1, wherein the coupling element is a capacitor.

11. The system of claim 1, wherein the flux qubit is a capacitively shunted flux qubit.

12. The system of claim 1, wherein the superconducting qubit is a fluxonium qubit.

13. A method comprising:
controlling a flux bias of a flux qubit such that a first transition frequency corresponding to a level transition of the flux qubit is resonant with a second transition frequency corresponding to a level transition of a superconducting qubit, the superconducting qubit being coupled to the flux qubit via a coupling element;
applying at least one microwave pulse to the flux qubit that drives the level transition of the flux qubit;
controlling the flux bias of the flux qubit to generate a persistent current in the flux qubit; and
measuring the persistent current in the flux qubit using a readout system.

14. The method of claim 13, further comprising, prior to controlling the flux bias of the flux qubit such that the first transition frequency is resonant with the second transition frequency, operating a superconducting qubit controller to perform at least one single-qubit gate on the superconducting qubit.

15. The method of claim 13, wherein the level transition of the flux qubit is a transition between |0 [symbol] and |1 [symbol] states of the flux qubit, and wherein the level transition of the superconducting qubit is a transition between |1 [symbol] and |2 [symbol] states of the superconducting qubit.

16. The method of claim 13, further comprising measuring a quantum state of the superconducting qubit based on the persistent current measured in the flux qubit.

17. The method of claim 13, wherein measuring the persistent current in the flux qubit comprises measuring a direction of current flowing in the flux qubit.

18. The method of claim 13, wherein measuring the persistent current in the flux qubit comprises generating a current in a superconducting circuit inductively coupled to the flux qubit.

19. The method of claim 13, comprising applying the at least one microwave pulse to the flux qubit that drives the level transition of the flux qubit according to one or more digital values.

20. The method of claim 13, wherein the flux qubit is a first flux qubit, wherein the superconducting qubit is a first superconducting qubit, wherein the coupling element is a first coupling element, wherein the at least one microwave pulse comprises a first microwave pulse and wherein the method further comprises:
generating the first microwave pulse from a microwave source having a single carrier frequency;
generating a second microwave pulse from the microwave source having the single carrier frequency;
controlling a flux bias of a second flux qubit such that a first transition frequency corresponding to a level transition of the second flux qubit is resonant with a second transition frequency corresponding to a level transition of a second superconducting qubit, the second superconducting qubit being coupled to the second flux qubit via a second coupling element; and
applying the second microwave pulse to the second flux qubit that drives the level transition of the second flux qubit.
